(19) United States
(12) Patent Application Publication
(10) Pub. No.: US 2024/0213424 A1
(43) Pub. Date: Jun. 27, 2024

(54) DISPLAY PANEL AND MANUFACTURING METHOD THEREOF

(71) Applicant: Shenzhen China Star Optoelectronics Semiconductor Display Technology Co., Ltd., Shenzhen, Guangdong (CN)

(72) Inventor: Liangfen ZHANG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/598,900

(22) PCT Filed: Jul. 16, 2021
(86) PCT No.: PCT/CN2021/106700

§ 371 Date: Feb. 29, 2024

(30) Foreign Application Priority Data
Jun. 16, 2021 (CN) 202110667066.6

(51) Int. Cl. H01L 33/62; H01L 25/16; H01L 27/12; H01L 33/54

(52) U.S. Cl. CPC H01L 33/62; H01L 25/167; H01L 27/124; H01L 33/54; H01L 2933/005; H01L 2933/0066

(57) ABSTRACT

A display panel and a manufacturing method thereof are provided. The display panel includes a substrate, a first metal layer, a first insulating layer, and a dam layer arranged in a stack. The first metal layer includes a first signal wiring. A light-emitting unit is bonded to the first signal wiring through a solder paste in a first opening of the first insulating layer and a second opening of the dam layer. A side of the dam layer away from the substrate is higher than or equal to a side of the solder paste away from the substrate. This application can prevent the solder paste from overflowing.

### TECHNICAL FIELD

The present application relates to a field of display technology, in particular to a display panel and a manufacturing method thereof.

### BACKGROUND

Mini LED/Micro LED (MLED) display panels have entered a stage of accelerated development in past two years, and are widely used in small and medium-sized display applications. Compared with organic light-emitting diode (OLED) panels, MLED displays show better performance in terms of cost, contrast, high brightness, and thin and light appearance.

A backplane process of MLED display panel is performed after a manufacturing of a thin-film transistor device layer is completed, which usually uses a surface mount technology (SMT) to a bond light-emitting unit to a bonding wiring, to realize light emission of the light-emitting unit. Its specific steps include: placing a screen on a substrate of the MLED. The screen is used to apply a solder paste to a position of the substrate corresponding to the bonding wiring of the light-emitting unit. The light-emitting unit is fixed on the bonding wiring of the substrate by the solder paste. However, in a process of bonding the light-emitting unit to the solder paste, a heated solder paste causes an overflow in an indefinite direction, which easily causes a fixed position of the light-emitting unit to shift.

### SUMMARY

### Technical Problem

An objective of the present application is to provide a display panel and a manufacturing method thereof to solve a problem of solder paste overflow during a process of bonding a light-emitting unit to the solder paste, which causes a fixed position of the light-emitting unit to shift.

### Technical Solutions of the Problems

### Technical Solutions

An embodiment of the present application provides a display panel including a display area and a non-display area, the display area and the non-display area are arranged adjacently, and the display panel includes:
a substrate;
a first metal layer located on a side of the substrate, wherein the first metal layer includes a first signal wiring located in the display area;
a first insulating layer located on a side of the first metal layer away from the substrate, wherein the first insulating layer is defined with a first opening, and the first opening exposes the first signal wiring;
a solder paste located in the first opening;
a dam layer located in the display area, wherein the dam layer is located on a side of the first insulating layer away from the substrate, and the dam layer and the solder paste mutually repel, the dam layer is defined with a second opening, and the second opening is arranged corresponding to the first opening; and
a light-emitting unit located on a side of the first signal wiring away from the substrate, wherein the light-emitting unit is located in the second opening, and the light-emitting unit is electrically connected to the first signal wiring through the solder paste;
wherein a side of the dam layer away from the substrate is higher than a side of the solder paste away from the substrate, or a side of the dam layer away from the substrate has a same height as a side of the solder paste away from the substrate.

In some embodiments, the dam layer extends from the display area to the non-display area.

In some embodiments, the dam layer further includes a groove located on a side of the dam layer away from the first insulating layer, and the groove is close to the second opening.

In some embodiments, the dam layer further includes a plurality of grooves, and the plurality of grooves are arranged around the second opening.

In some embodiments, a cross-sectional diameter of a side of the second opening close to the substrate is greater than a cross-sectional diameter of a side of the second opening away from the substrate.

In some embodiments, the second opening penetrates the first opening, and the dam layer covers a wall of the first opening.

In some embodiments, the display panel further includes a transparent protective layer located on a side of the dam layer away from the first insulating layer, and the transparent protective layer covers the light-emitting unit.

In some embodiments, the light-emitting unit includes a positive terminal and a negative terminal located adjacent to the positive terminal. The solder paste includes a first part and a second part, the first part is arranged corresponding to the positive terminal, and the second part is arranged corresponding to the negative terminal. The positive terminal is connected to the first part, and the negative terminal is connected to the second part. Wherein the dam layer is provided between the first part and the second part.

In some embodiments, a thickness of the dam layer is greater than or equal to 4 micrometers.

In some embodiments, the display panel further includes a second metal layer located between the first metal layer and the substrate, wherein the second metal layer includes a third signal wiring, and the first signal wiring is connected to the third signal wiring.

An embodiment of the present application further provides a display panel including a display area and a non-display area, the display area and the non-display area are arranged adjacently, and the display panel includes:
a substrate;
a first metal layer located on a side of the substrate, wherein the first metal layer comprises a first signal wiring located in the display area;
a first insulating layer located on a side of the first metal layer away from the substrate, wherein the first insulating layer is defined with a first opening, and the first opening exposes the first signal wiring;
a solder paste located in the first opening;
a dam layer extending from the display area to the non-display area, wherein the dam layer is located on a side of the first insulating layer away from the substrate, and the dam layer and the solder paste mutually repel, the dam layer is defined with a second opening and a groove, and the second opening is arranged corresponding to the first opening, and the groove is located on a side of the dam layer away from the first insulating layer, and the groove is close to the second opening; and
a light-emitting unit located on a side of the first signal wiring away from the substrate, wherein the light-emitting unit is located in the second opening, and the light-emitting unit is electrically connected to the first signal wiring through the solder paste;
wherein a side of the dam layer away from the substrate is higher than a side of the solder paste away from the substrate, or a side of the dam layer away from the substrate has a same height as a side of the solder paste away from the substrate.

In some embodiments, the dam layer includes a plurality of grooves arranged around the second opening.

In some embodiments, a cross-sectional diameter of a side of the second opening close to the substrate is greater than a cross-sectional diameter of a side of the second opening away from the substrate.

In some embodiments, the second opening penetrates the first opening, and the dam layer covers a wall of the first opening.

In some embodiments, the display panel further includes a transparent protective layer located on a side of the dam layer away from the first insulating layer, and the transparent protective layer covers the light-emitting unit.

In some embodiments, the light-emitting unit includes a positive terminal and a negative terminal located adjacent to the positive terminal. The solder paste includes a first part and a second part, the first part is arranged corresponding to the positive terminal, and the second part is arranged corresponding to the negative terminal. The positive terminal is connected to the first part, and the negative terminal is connected to the second part. Wherein the dam layer is provided between the first part and the second part.

In some embodiments, a thickness of the dam layer is greater than or equal to 4 micrometers.

In some embodiments, the display panel further includes a second metal layer located between the first metal layer and the substrate, wherein the second metal layer includes a third signal wiring, and the first signal wiring is connected to the third signal wiring.

An embodiment of the present application further provides a manufacturing method of a display panel, including:
forming a first metal layer on the substrate;
patterning the first metal layer to form a first signal wiring located in a display area of the display panel;
forming a first insulating layer on the first metal layer;
etching the first insulating layer to form a first opening to expose the first signal wiring;
forming a dam layer on the first insulating layer located in the display area;
patterning the dam layer to form a second opening located corresponding to the first opening;
applying a solder paste to the first opening and the second opening, wherein the solder paste and the dam layer mutually repel, and a side of the dam layer away from the substrate is higher than a side of the solder paste away from the substrate, or a side of the dam layer away from the substrate has a same height as a side of the solder paste away from the substrate; and
bonding the light-emitting unit to the solder paste.

In some embodiments, the step of patterning the dam layer to form the second opening includes:
performing a local photolithography process on the dam layer with a mask; and
dipping the dam layer subjected to the local photolithography process in a developing solution to perform a developing process to form a second opening.

### Beneficial Effect of the Invention

### Beneficial Effect

The present application provides a display panel. The display panel includes a display area and a non-display area arranged adjacently. The display panel includes a substrate, a first metal layer, a first insulating layer, a solder paste, a dam layer, and a light-emitting unit. The first metal layer is located on one side of the substrate. The first metal layer includes a first signal wiring located in the display area. The first insulating layer is located on a side of the first metal layer away from the substrate and is defined with a first opening. The first opening exposes the first signal wiring. The dam layer is located on a side of the first insulating layer away from the substrate. The dam layer and the solder paste mutually repel. The dam layer is defined with a second opening arranged corresponding to the first opening. The light-emitting unit is located in the second opening. The light-emitting unit is electrically connected to the first signal wiring through the solder paste. In the present application, a side of the dam layer away from the substrate is higher than a side of the solder paste away from the substrate, or a side of the dam layer away from the substrate is as high as a side of the solder paste away from the substrate. It can prevent the solder paste from overflowing during a process of bonding the light-emitting unit to the solder paste. Furthermore, a relative position of the light-emitting unit and the first signal wiring is prevented from being shift. In addition, the light-emitting unit and the adjacent signal line are prevented from being incorrectly bonded, to ensure a normal display of the display panel.

### BRIEF DESCRIPTION OF THE DRAWINGS

### Description of the Drawings

In order to explain the technical solutions of embodiments of the present application more clearly, the following briefly introduces the drawings that need to be used in the description of the embodiments of the present application. Obviously, the drawings in the description are only some embodiments and implementations of the application. For those of ordinary skill in the art, other drawings can be obtained based on these drawings without doing creative work.

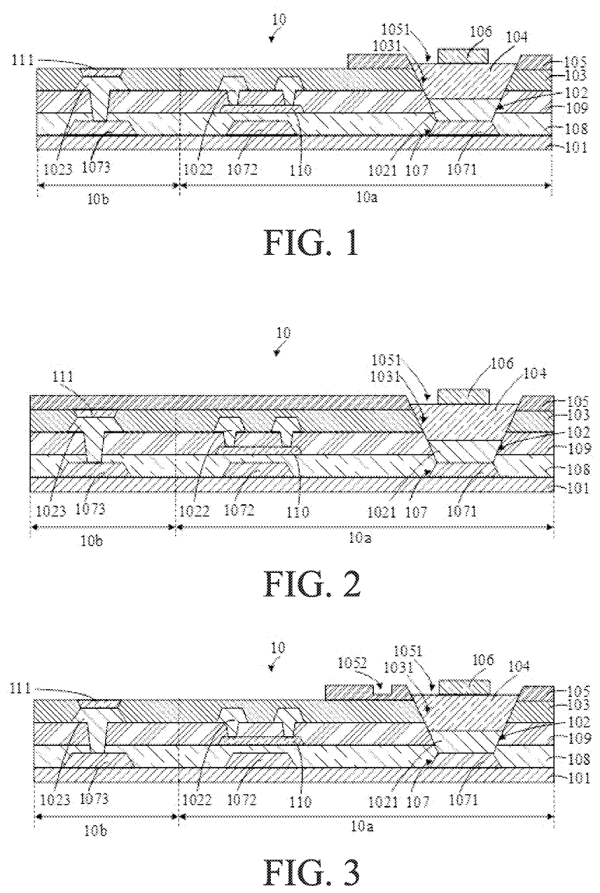

FIG. 1 is a schematic diagram of a first structure of a display panel provided by the present application.

FIG. 2 is a schematic diagram of a second structure of the display panel provided by the present application.

FIG. 3 is a schematic diagram of a third structure of the display panel provided by the present application.

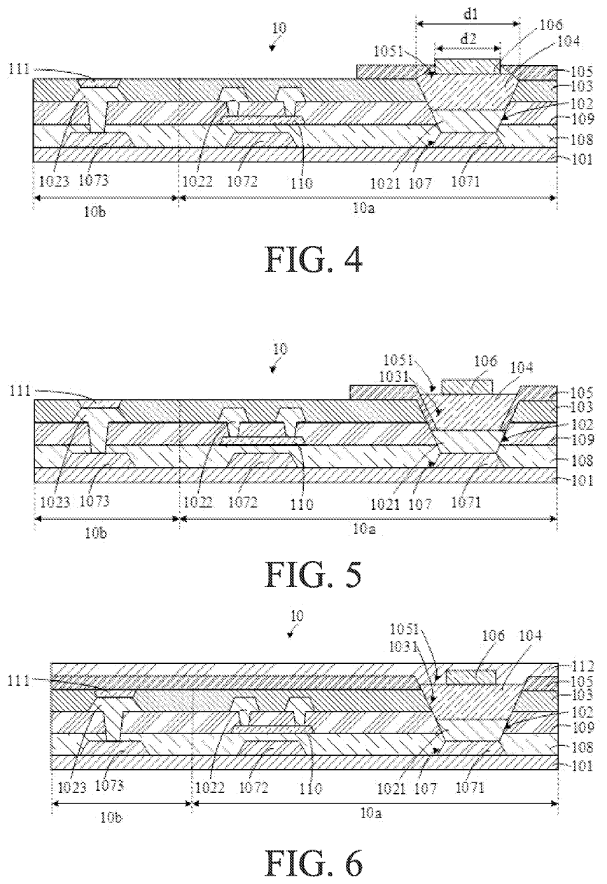

FIG. 4 is a schematic diagram of a fourth structure of the display panel provided by the present application.

FIG. 5 is a schematic diagram of a fifth structure of the display panel provided by the present application.

FIG. 6 is a schematic diagram of a sixth structure of the display panel provided by the present application.

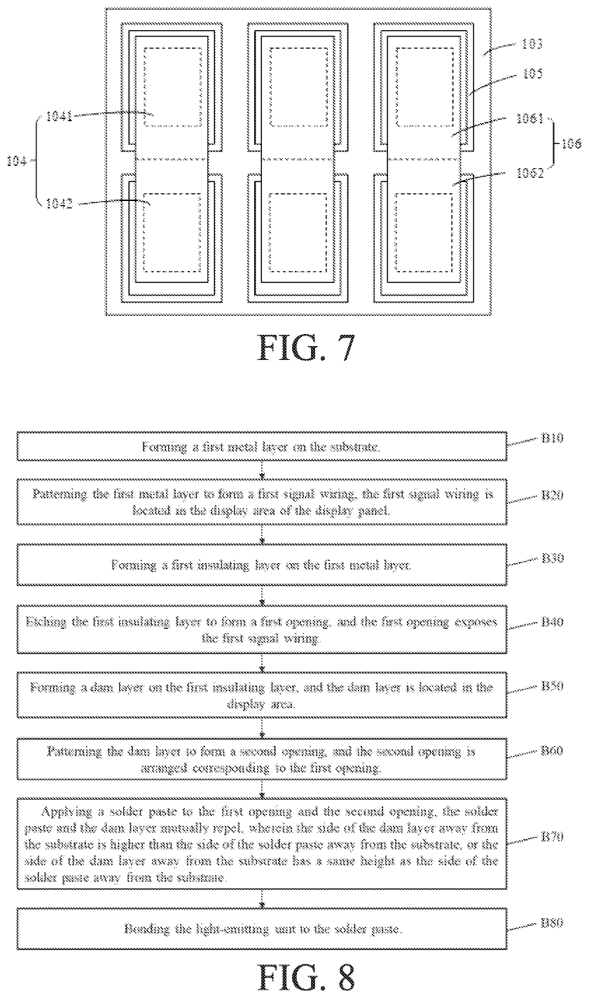

FIG. 7 is a schematic diagram of a planar structure of a display area of the display panel provided by the present application.

FIG. 8 is a flow chart of a manufacturing method of the display panel provided by the present application.

### EMBODIMENTS OF THE INVENTION

### Implementation Ways of the Invention

The technical solutions in the embodiments of the present application will be clearly and completely described with reference to the drawings in the embodiments of the present application. Obviously, the embodiments are only a part of the embodiments of the present application, rather than all the embodiments. Based on the embodiments in this application, all other embodiments obtained by those skilled in the art without doing creative work shall fall within the protection scope of the present application.

It should be noted that the sequential terms “first” and “second” mentioned in the present application do not represent any order, quantity, or importance, but are used to distinguish different parts. The directional terms “above”, “below”, “left”, and “right” mentioned in the present application are only directions referring to the attached drawings. Positional terms such as “one side” and “the other side” mentioned in the present application are only used to distinguish different parts. Therefore, the sequential terms, directional terms, and positional terms are used to explain and understand the present application, but not to limit the present application. In the present application, unless expressly stipulated and defined otherwise, the first feature on “one side”, “upper” or “lower” of the second feature may include direct contact between the first and second features. It can also include that the first feature and second feature are not in direct contact but in contact with another feature between them. Throughout the specification, the same reference numerals denote the same elements. Because the size and thickness of each component illustrated in the drawings are for convenience of description, the present disclosure is not necessarily limited to the illustrated size and thickness of each component.

As shown in FIG. 1, the display panel 10 includes a display area 10a and a non-display area 10b arranged adjacently. The display area 10a refers to an area where the display panel 10 displays an image. The non-display area 10b is an area of the display panel 10 excluding the display area 10a. The display panel 10 includes a substrate 101, a first metal layer 102, a first insulating layer 103, a solder paste 104, a dam layer 105, and a light-emitting unit 106.

The first metal layer 102 is located on one side of the substrate 101. The first metal layer 102 includes a first signal wiring 1021, a source or drain 1022 of a thin film transistor, and a second signal wiring 1023. The first signal wiring 1021, the source or drain 1022 of the thin film transistor, and the second signal wiring 1023 are simultaneously formed during the patterning process of the first metal layer 102.

The first signal wiring 1021 and the source or drain 1022 are located in the display area 10a of the display panel 10. The second signal wiring 1023 is located in the non-display area 10 b of the display panel 10.

The first insulating layer 103 is located on a side of the first metal layer 102 away from the substrate 101. The first insulating layer 103 covers the first metal layer 102. The first insulating layer 103 includes a first opening 1031, the first opening 1031 is located in the display area 10a, and the first opening 1031 exposes the first signal wiring 1021. The first opening 1031 is filled with a solder paste 104. The first signal wiring 1021 is bonded to the solder paste 104.

The light-emitting unit 106 is located on a side of the first signal wiring 1021 away from substrate 101. The light-emitting unit 106 is located in the display area 10a. The light-emitting unit 106 is electrically connected to the first signal wiring 1021 through the solder paste 104. The first signal wiring 1021 provides electrical signals for the light-emitting unit 106 to realize the emission of the light-emitting unit 106.

It can be understood that there are a plurality of light-emitting units 106 in the display panel 10. In this application, one light-emitting unit 106 is taken as an example, but it is not a limitation to this application. The light-emitting unit 106 may be a miniature light-emitting diode. The light-emitting unit 106 can emit light of any color according to the requirements of the display panel 10. For example, the light-emitting unit 106 may emit red light, green light, or blue light respectively, to realize the color display of the display panel 10. The light-emitting unit 106 may also emit white light, which is matched with a color filter to realize a color display of the display panel 10.

The dam layer 105 is located in the display area 10a. The dam layer 105 is defined with a second opening 1051. The second opening 1051 is arranged corresponding to the first opening 1031. The dam layer 105 is defined with a second opening 1051. The second opening 1051 is arranged corresponding to the first opening 1031. The light-emitting unit 106 is located in the second opening 1051. Wherein, a side of the dam layer 105 away from the substrate 101 is higher than a side of the solder paste 104 away from the substrate 101.

It can be understood that the side of the dam layer 105 away from the substrate 101 may have the same height as the side of the solder paste 104 away from the substrate 101.

The material of the dam layer 105 is an organic material that repels the solder paste 104. The material of the dam layer in the present application is an organic material. A simple coating process can be performed to form dam layer 105 on the first insulating layer 103, which is beneficial to reduce the process difficulty and shorten the processing time.

The mutual repulsion of the dam layer 105 and the solder paste 104 means that the surface molecules of the dam layer 105 and the constituent materials of the solder paste 104 repel each other. When the solder paste is in a liquid state, the surface of the dam layer 105 is not easy to adhere to the solder paste 104. The dam layer 105 and the solder paste 104 mutually repel, which is similar to the hydrophobicity of waterproof material.

The dam layer 105 and the solder paste 104 repel each other, and the side of the dam layer 105 away from the substrate 101 is higher than the side of the solder paste 104 away from the substrate 101 or the side of the dam layer 105 away from the substrate 10 and the side of the solder paste 104 away from the substrate 101 have the same height. It can prevent the solder paste 104 from overflowing during the process of bonding the light-emitting unit 106 to the solder paste 104, thereby preventing the relative position of the light-emitting unit 106 and the first signal wiring 1021 from being shift. Meanwhile, the overflow of the solder paste 104 may easily lead to incorrect connections between the signal wiring in the display panel 10, thereby affecting the normal display of display panel 10. The solder paste 104 is electrically conductive, so that the side of the dam layer 105 away from the substrate 101 is higher than the side of the solder paste 104 away from the substrate 101, or the side of the dam layer 105 away from the substrate 101 has a same height as the side of the solder paste 104 away from the substrate 101 can prevent the solder paste 104 from overflowing to the area corresponding to the first insulating layer 103. It is possible to prevent incorrect connections between the signal wiring in the display panel 10 and to ensure the normal display of display panel 10.

The thickness of the dam layer 105 is greater than or equal to 4 micrometers. Specifically, the thickness of the dam layer 105 can be 4 micrometers, 6 micrometers, 10 micrometers, 15 micrometers, 20 micrometers, 30 micrometers, 50 micrometers, 100 micrometers, 200 micrometers, or 500 micrometers.

As shown in FIG. 1, the display panel 10 further includes a second metal layer 107, a second insulating layer 108, a third insulating layer 109, a semiconductor layer 110, and a protective layer 111.

The second metal layer 107 is located between the first metal layer 102 and the substrate 101. Specifically, the second metal layer 107 is in contact with the substrate 101. The second metal layer 107 includes a third signal wiring 1071, a gate 1072, and a fourth signal wiring 1073. The third signal wiring 1071 and the gate 1072 are located in the display area 10a of the display panel 10. The fourth signal wiring 1073 is located in the non-display area 10b of the display panel 10. The third signal wiring 1071, the gate 1072, and the fourth signal wiring 1073 are simultaneously formed during the patterning process of the second metal layer 107.

The first signal wiring 1021 is connected to the third signal wiring 1071. The connection between the third signal wiring 1071 and the first signal wiring 1021 can effectively increase the area of the first signal wiring and reduce the resistance of the first signal wiring, thereby effectively preventing the voltage drop on the first signal wiring.

The second insulating layer 108 is located on the side of the second metal layer 107 away from the substrate 101. Wherein, the second insulating layer 108 covers the second metal layer 107.

The third insulating layer 109 is located on the side of the second insulating layer 108 away from the second metal layer 107. Wherein, the third insulating layer 109 covers the semiconductor layer 110.

In the display area 10a of the display panel 10, the gate 1072, the semiconductor layer 110, and the source or drain 1022 together form a thin film transistor. The aforesaid thin film transistor is used to control the lighting and extinction of the light-emitting unit 106.

Because the structural schematic diagram of the display panel 10 provided in the present application is only a structural schematic diagram from a certain angle of the display panel 10, the connection relationship of the components of the display panel 10 cannot be reflected one by one in FIG. 1. Those skilled in the art can understand that in FIG. 1, the thin film transistor formed by the gate 1072, the semiconductor layer 110, and the source or drain 1022 controls the light-emitting unit 106 on one side thereof.

The non-display area 10b of the display panel 10 includes a second signal wiring 1023, a fourth signal wiring 1073, and a protective layer 111. The second signal wiring 1023 is connected to the fourth signal wiring 1073 through a via hole. The second signal wiring 1023 and the fourth signal wiring 1073 cooperate with the signal wiring in the display area 10a to realize the display of the display panel 10. The protective layer 111 is used to protect the second signal wiring 1023 which can prevent the second signal wiring 1023 from being thermally oxidized due to high temperature during the manufacturing process. The material of the protective layer 111 can be indium tin oxide (ITO).

As shown in FIG. 2, the dam layer 105 can extend from the display area 10a of the display panel 10 to the non-display area 10b of the display panel 10. Specifically, the dam layer 105 covers e source or drain 1022 and the protective layer 111.

The dam layer 105 extending from the display area 10a to the non-display area 10b can function to isolate water and oxygen. The dam layer 105 covering the source or drain 1022 and the protective layer 111 can prevent water vapor from entering the source or drain 1022 and the second signal wiring 1023, which is beneficial to increase the service life of the display panel 10.

The other structures of the display panel 10 in FIG. 2 are the same as those in FIG. 1, and will not be repeated herein.

As shown in FIG. 3, the dam layer 105 may also include a groove 1052. Specifically, the groove 1052 is located on the side of the dam layer 105 away from the first insulating layer 103. The groove 1052 is close to the second opening 1051.

In the present application, the groove 1052 can be defined at a position of the display panel 10 close to the second opening 1051. When the coating amount of the solder paste 104 is too much, the solder paste 104 overflowing from the second opening 1051 can be stored in the groove 1052 to prevent the overflowing solder paste 104 from being connected to other devices or metal wiring, to ensure the normal display of the display panel 10.

In some embodiments, a plurality of grooves 1052 can be defined on the side of the dam layer 105 away from the first insulating layer 103. The plurality of grooves 1052 can be defined around the second opening 1051 and can further prevent the solder paste 104 from overflowing.

The other structures of the display panel 10 in FIG. 3 are the same as those in FIG. 1, and will not be repeated herein.

As shown in FIG. 4, in the dam layer 105, the cross-sectional diameter d1 of the second opening 1051 on the side close to the substrate 101 can be larger than the cross-sectional diameter d2 of the second opening 1051 on the side away from the substrate 101. That is, the cross section of the second opening 1051 in the thickness direction has an inverted trapezoid shape. In the present application, setting d1 to be greater than d2 can further prevent the solder paste 104 from overflowing. Meanwhile, d1 greater than d2 can further have the effect of fixing the light-emitting unit 106.

The other structures of the display panel 10 in FIG. 4 are the same as those in FIG. 1, and will not be repeated herein.

As shown in FIG. 5, the second opening 1051 in the dam layer 105 penetrates the first opening 1031. The dam layer 105 can cover the wall of the first opening 1031. The dam layer 105 covering the wall of the first opening 1031 can prevent the solder paste 104 from penetrating along the wall of the first opening 1031 to the gap between the dam layer 105 and the first insulating layer 103 and the gap between the first insulating layer 103 and the third insulating layer 109, to prevent the solder paste 104 from being connected to other signal wiring or the light-emitting unit 106 through aforesaid gaps. In addition, because the dam layer 105 and the solder paste 104 repel each other, the dam layer 105 covering the wall of the first opening 1031 can further prevent the solder paste 104 from overflowing.

The other structures of the display panel 10 in FIG. 5 are the same as those in FIG. 1, and will not be repeated herein.

As shown in FIG. 6, the display panel 10 further include a transparent protective layer 112. The transparent protective layer 112 is located on the side of the dam layer 105 away from the first insulating layer 103. The transparent protective layer 112 covers the light-emitting unit 106. The transparent protective layer 112 covers the display area 10a and the non-display area 10b of the display panel 10, which can prevent water and oxygen from entering the light-emitting unit 106 and the metal wiring of the display panel 10. It is beneficial to increase the service life of the display panel 10. In addition, the transparent protective layer 112 facilitates the transmission of light in the light-emitting unit 106, which can increase the service life of the display panel 10 while ensuring the display effect of the display panel 10.

The other structures of the display panel 10 in FIG. 6 are the same as those in FIG. 1, and will not be repeated herein.

With reference to FIG. 1 and FIG. 7, FIG. 7 is a schematic diagram of a planar structure of a display panel in a display area provided by an embodiment of the application.

The light-emitting unit 106 includes a positive terminal 1061 and a negative terminal 1062. The positive terminal 1061 and the negative terminal 1062 are connected to the solder paste 104 respectively. The positive terminal 1061 and the negative terminal 1062 are adjacent to each other. The solder paste 104 includes a first part 1041 and a second part 1042. The first part 1041 is arranged corresponding to the positive terminal 1061, and the second part 1042 is arranged corresponding to the negative terminal 1062. The positive terminal 1061 is connected to the first part 1011, and the negative terminal 1062 is connected to the second part 1042. Wherein, a dam layer 105 is provided between the first part 1041 and the second part 1042. That is, the dam layer 105 is provided at a position of the first insulating layer 103 of the display panel 10 corresponding to the positive terminal 1061 and the negative terminal 1062 of the light emitting unit 106 to ensure that the first part 1041 of the solder paste 104 and the second part 1042 of the solder paste 104 are not connected.

In the present application, a dam layer 105 is provided on the first insulating layer 103 corresponding to the area between the positive terminal 1061 and the negative terminal 1062 of the same light-emitting unit 106 to ensure that the first part 1041 of the solder paste 104 is not connected to the second part 1042 of the solder paste 104. It prevents the electrical signals of the positive terminal 1061 and the negative terminal 1062 from interfering with each other in the same light-emitting unit 106 and ensures that the electrical signals of the positive terminal 1061 and the negative terminal 1062 are independent of each other.

In some embodiments, the dam layer 105 can extend from the display area 10 a of the display panel 10 to the non-display area 10 b of the display panel 10. In FIG. 7, a schematic plan view of the dam layer 105 in the display area 10a is taken as an example for description, but it is not a limitation of the present application.

The present application provides a display panel. The display panel includes a display area and a non-display area arranged adjacently. The display panel includes a substrate, a first metal layer, a first insulating layer, a solder paste, a dam layer, and a light-emitting unit. The first metal layer is located on one side of the substrate. The first metal layer includes a first signal wiring. The first signal wiring is located in the display area. The first insulating layer is located on a side of the first metal layer away from the substrate. The first insulating layer is defined with a first opening. The first opening exposes the first signal wiring. The dam layer is located on a side of the first insulating layer away from the substrate. The dam layer and the solder paste mutually repel. The dam layer is defined with a second opening. The second opening is arranged corresponding to the first opening. The light-emitting unit is located in the second opening. The light-emitting unit is electrically connected to the first signal wiring through the solder paste. In the present application, a side of the dam layer away from the substrate is higher than a side of the solder paste away from the substrate, or a side of the dam layer away from the substrate is as high as a side of the solder paste away from the substrate. It can prevent the solder paste from overflowing during the process of bonding the light-emitting unit to the solder paste. Furthermore, a relative position of the light-emitting unit and the first signal wiring is prevented from being shift, and the light-emitting unit and the adjacent signal line are prevented from being incorrectly bonded, so as to ensure a normal display of the display panel.

Correspondingly, the embodiment of the present application further provides a manufacturing method of a display panel. As shown in FIG. 8, FIG. 8 is a flow chart of a manufacturing method of the display panel provided by the present application. The manufacturing method of the display panel specifically includes the following steps:

Step B10: forming a first metal layer on the substrate.

The substrate may be a rigid substrate, such as a glass substrate. The substrate may also be a flexible substrate, such as a substrate formed of polyimide or polyester material. Before forming the first metal layer, other film layers may be formed on the substrate according to the requirements of the display panel.

The process of forming the first metal layer can be electrochemical deposition, chemical vapor deposition, or metal layer sputtering. The aforesaid method of forming the first metal layer can be selected according to the actual needs of the display panel, which is not limited herein. The material of the first metal layer may be at least one of copper (Cu), molybdenum (Mo), or aluminum (Al).

Step B20: patterning the first metal layer to form a first signal wiring, the first signal wiring is located in the display area of the display panel.

Specifically, after the first metal layer is formed, the first metal layer can be patterned by a laser cutting or dry etching process to form the first signal wiring. The laser cutting process means that a laser beam is irradiated to the surface of the first metal layer. The first metal layer irradiated by the laser receives strong thermal energy, and its temperature rises sharply. The high temperature causes the first metal layer of this part to melt, thereby forming a corresponding pattern. The dry etching process refers to a technique that uses oxidizing plasma to etch the first metal layer. The aforesaid metal patterning process of the first metal layer can be selected according to the actual needs of the display panel, and is not limited herein.

The formed first signal wiring is located in the display area of the display panel.

Step B30: forming a first insulating layer on the first metal layer.

After the first metal layer is formed, a first insulating layer can be formed on the first metal layer by a chemical vapor deposition method. The chemical vapor deposition refers to a method of forming a first insulating layer by chemical reaction on the surface of a substrate by using one or several vapor-phase compounds or simple substances containing thin film elements. In the present application, the material of the first insulating layer can be silicon nitride (SiₓN_{y}). The raw materials used to form the first insulating layer by chemical vapor deposition are monosilane (SiH₄) and ammonia (NH₃). SiH₄ and NH₃ react on the surface of the first metal layer, and the generated SiₓN_{y} solid is deposited on the surface of the first metal layer to form a first insulating layer.

Step B40: etching the first insulating layer to form a first opening, and the first opening exposes the first signal wiring.

Specifically, the first insulating layer can be etched through a dry etching process to form the first opening. The first insulating layer can be etched using an oxidizing plasma formed of oxygen (O₂) and nitrogen fluoride (NF₃). The oxidizing plasma chemically reacts with SiₓN_{y} of the first insulating layer to form a first opening, wherein the first opening exposes the first signal wiring.

Step B50: forming a dam layer on the first insulating layer, and the dam layer is located in the display area.

Specifically, an organic material mutually repelling the solder paste is coated on the first insulating layer, thereby forming a dam layer.

Step B60: patterning the dam layer to form a second opening, and the second opening is arranged corresponding to the first opening.

Specifically, the step of forming the second opening includes:

Step B61: performing local illumination process on the dam layer with a mask.

After the dam layer is formed, a mask aligner with a mask can be used to perform local photolithography process on the dam layer. The mask is preset with corresponding patterns. The mask is arranged between the light source and the dam layer. During the photolithography process, the patterns on the mask block the light, so that part of the light from the light source is irradiated on the dam layer.

Step B62: dipping the dam layer subjected to the local photolithography process in a developing solution to perform a developing process to form a second opening.

The dam layer after being subjected to the local photolithography process is placed in a developing solution to perform a developing process. During the local photolithography process of the dam layer through the mask, the chemical properties of the dam layer irradiated by the light are changed, so that the developing solution can remove a part of the dam layer, thereby forming the second opening. The second opening is arranged corresponding to the first opening.

Step B70: applying a solder paste to the first opening and the second opening, the solder paste and the dam layer mutually repel, wherein the side of the dam layer away from the substrate is higher than the side of the solder paste away from the substrate, or the side of the dam layer away from the substrate has a same height as the side of the solder paste away from the substrate.

Specifically, a solder paste can be placed on the surface of a printing screen, and a certain pressure is applied to the solder paste, and the solder paste passes through the through-holes on the printing screen to be coated in the first opening and the second opening. The solder paste and the dam layer mutually repel. That is, the solder paste does not easily stay on the surface of the dam layer. After the solder paste is applied, the side of the dam layer away from the substrate is higher than the side of the solder paste away from the substrate, or the side of the dam layer away from the substrate has the same height as the side of the solder paste away from the substrate.

Step B80: bonding the light-emitting unit to the solder paste.

The light-emitting unit is bonded to the solder paste in the first opening and the second opening to be fixed in the display panel.

In some embodiments, after the light-emitting unit is bonded to the solder paste, a transparent protective layer may be formed on the light-emitting unit. The transparent protective layer covers the light-emitting unit. Meanwhile, the transparent protective layer covers the display area and the non-display area of the display panel. The transparent protective layer can prevent water and oxygen from entering the light-emitting unit of the display panel and the metal wiring of the display panel, which is beneficial to increase the service life of the display panel.

The embodiment of the present application provides a manufacturing method of a display panel. The manufactured display panel includes a substrate, a first metal layer, a first insulating layer, a solder paste, a dam layer, and a light-emitting unit. The first metal layer is located on one side of the substrate. The first metal layer includes a first signal wiring. The first signal wiring is located in the display area. The first insulating layer is located on a side of the first metal layer away from the substrate. The first insulating layer is defined with a first opening. The first opening exposes the first signal wiring. The dam layer is located on a side of the first insulating layer away from the substrate. The dam layer and the solder paste mutually repel. The dam layer is defined with a second opening. The second opening is arranged corresponding to the first opening. The light-emitting unit is located in the second opening. The light-emitting unit is electrically connected to the first signal wiring through the solder paste. In the present application, a side of the dam layer away from the substrate is higher than a side of the solder paste away from the substrate, or a side of the dam layer away from the substrate is as high as a side of the solder paste away from the substrate. It can prevent the solder paste from overflowing during the process of bonding the light-emitting unit to the solder paste. Furthermore, a relative position of the light-emitting unit and the first signal wiring is prevented from being shift, and the light-emitting unit and the adjacent signal line are prevented from being incorrectly bonded, to ensure a normal display of the display panel.

As mentioned above, although the embodiments of the present application are described in detail above, the embodiments are not intended to limit the present application, and those of ordinary skill in the art should understand: It is still possible to modify the technical solutions described in the foregoing embodiments, or equivalently replace some of the technical features. However, these modifications or replacements do not cause the essence of the corresponding technical solutions to deviate from the scope of the technical solutions of the embodiments of the present application.

1. A display panel, comprising a display area and a non-display area adjacent to the display area, wherein the display panel further comprises:
a substrate;
a first metal layer located on a side of the substrate, wherein the first metal layer comprises a first signal wiring located in the display area;
a first insulating layer located on a side of the first metal layer away from the substrate, wherein the first insulating layer is defined with a first opening, and the first opening exposes the first signal wiring;
a solder paste located in the first opening;
a dam layer located in the display area, wherein the dam layer is located on a side of the first insulating layer away from the substrate, the dam layer and the solder paste mutually repel, the dam layer is defined with a second opening, and the second opening is arranged corresponding to the first opening; and
a light-emitting unit located on a side of the first signal wiring away from the substrate, wherein the light-emitting unit is located in the second opening, and the light-emitting unit is electrically connected to the first signal wiring through the solder paste;
wherein a side of the dam layer away from the substrate is higher than a side of the solder paste away from the substrate, or a side of the dam layer away from the substrate has a same height as a side of the solder paste away from the substrate.

2. The display panel of claim 1, wherein the dam layer extends from the display area to the non-display area.

3. The display panel of claim 1, wherein the dam layer further comprises a groove located on a side of the dam layer away from the first insulating layer, and the groove is close to the second opening.

4. The display panel of claim 1, wherein the dam layer further comprises a plurality of grooves, and the plurality of grooves are arranged around the second opening.

5. The display panel of claim 1, wherein a cross-sectional diameter of a side of the second opening close to the substrate is greater than a cross-sectional diameter of a side of the second opening away from the substrate.

6. The display panel of claim 1, wherein the second opening penetrates the first opening, and the dam layer covers a wall of the first opening.

7. The display panel of claim 1, further comprising a transparent protective layer located on a side of the dam layer away from the first insulating layer, and the transparent protective layer covers the light-emitting unit.

8. The display panel of claim 1, wherein the light-emitting unit comprises a positive terminal and a negative terminal located adjacent to the positive terminal; the solder paste comprises a first part and a second part, the first part is arranged corresponding to the positive terminal, and the second part is arranged corresponding to the negative terminal; the positive terminal is connected to the first part, and the negative terminal is connected to the second part; and wherein the dam layer is provided between the first part and the second part.

9. The display panel of claim 1, wherein a thickness of the dam layer is greater than or equal to 4 micrometers.

10. The display panel of claim 1, further comprising a second metal layer located between the first metal layer and the substrate; wherein the second metal layer comprises a third signal wiring, and the first signal wiring is connected to the third signal wiring.

11. A display panel comprising a display area and a non-display area adjacent to the display area, and further comprising:
a substrate;
a first metal layer located on a side of the substrate, wherein the first metal layer comprises a first signal wiring located in the display area;
a first insulating layer located on a side of the first metal layer away from the substrate, wherein the first insulating layer is defined with a first opening, and the first opening exposes the first signal wiring;
a solder paste located in the first opening;
a dam layer extending from the display area to the non-display area, wherein the dam layer is located on a side of the first insulating layer away from the substrate, the dam layer and the solder paste mutually repel, the dam layer is defined with a second opening and a groove, and the second opening is arranged corresponding to the first opening, and the groove is located on a side of the dam layer away from the first insulating layer, and the groove is close to the second opening; and
a light-emitting unit located on a side of the first signal wiring away from the substrate, wherein the light-emitting unit is located in the second opening, and the light-emitting unit is electrically connected to the first signal wiring through the solder paste;
wherein a side of the dam layer away from the substrate is higher than a side of the solder paste away from the substrate, or a side of the dam layer away from the substrate has a same height as a side of the solder paste away from the substrate.

12. The display panel of claim 11, wherein the dam layer comprises a plurality of grooves arranged around the second opening.

13. The display panel of claim 11, wherein a cross-sectional diameter of a side of the second opening close to the substrate is greater than a cross-sectional diameter of a side of the second opening away from the substrate.

14. The display panel of claim 11, wherein the second opening penetrates the first opening, and the dam layer covers a wall of the first opening.

15. The display panel of claim 11, further comprising a transparent protective layer located on a side of the dam layer away from the first insulating layer, and the transparent protective layer covers the light-emitting unit.

16. The display panel of claim 11, wherein the light-emitting unit comprises a positive terminal and a negative terminal located adjacent to the positive terminal; the solder paste comprises a first part and a second part, the first part is arranged corresponding to the positive terminal, and the second part is arranged corresponding to the negative terminal; the positive terminal is connected to the first part, and the negative terminal is connected to the second part; and wherein the dam layer is provided between the first part and the second part.

17. The display panel of claim 11, wherein a thickness of the dam layer is greater than or equal to 4 micrometers.

18. The display panel of claim 11, further comprising a second metal layer located between the first metal layer and the substrate; wherein the second metal layer comprises a third signal wiring, and the first signal wiring is connected to the third signal wiring.

19. A manufacturing method of a display panel, comprising:
forming a first metal layer on a substrate;
patterning the first metal layer to form a first signal wiring located in a display area of the display panel;
forming a first insulating layer on the first metal layer;
etching the first insulating layer to form a first opening to expose the first signal wiring;
forming a dam layer on the first insulating layer and located in the display area;
patterning the dam layer to form a second opening located corresponding to the first opening;
applying a solder paste to the first opening and the second opening, wherein the solder paste and the dam layer mutually repel, and a side of the dam layer away from the substrate is higher than a side of the solder paste away from the substrate, or a side of the dam layer away from the substrate has a same height as a side of the solder paste away from the substrate; and
bonding a light-emitting unit to the solder paste.

20. The manufacturing method of the display panel of claim 19, wherein the step of patterning the dam layer to form the second opening comprises:
performing a local photolithography process with a mask on the dam layer; and
dipping the dam layer subjected to the local photolithography process in a developing solution to perform a developing process to form a second opening.
